(19) United States
(12) Patent Application Publication
(10) Pub. No.: US 2018/0286733 A1
(43) Pub. Date: Oct. 4, 2018

(54) DIE CARRIER DEVICE AND METHOD

(71) Applicant: Intel Corporation, Santa Clara, CA (US)

(72) Inventors: Mingzhi Mindy Dai, Chandler, AZ (US); Tristan W. Day, Portland, OR (US); Chuan Pei Lim, Gelugor (MY)

(21) Appl. No.: 15/474,762

(22) Filed: Mar. 30, 2017

(51) Int. Cl. H01L 21/683; H01L 21/677; B29C 59/00

(52) U.S. Cl. CPC H01L 21/6835; H01L 21/67721; H01L 21/67144; B29C 59/005; H01L 2221/68313; H01L 21/6773

(57) ABSTRACT

A system and method for constructing a carrier tape for storing and transporting die is disclosed. A system creates a depressed cavity in the computer system carrier tape without creating a hole through the tape, wherein the cavity is defined by four corners, with four edges between the corners and wherein the cavity is conformed to hold a silicon die. The system creates at least one side pocket along at least one of the four edges, wherein the side pocket allows displaced air to escape, but does not allow the die to shift position in the depressed cavity.

### TECHNICAL FIELD

Embodiments described herein generally relate to tape carrier improvement.

### BACKGROUND

Microelectronic devices operate using integrated circuits embedded in a small silicon die. As time has gone on, the size of the dies (and the size of the integrated circuit components) have shrunk dramatically. As such, these dies are very delicate and can be difficult to store or ship without damage. One technique to move dies is to use carrier tape with a series of pockets. Carrier tape provides protection to integrated circuits and other devices from physical and electro-static discharge (ESD) damage during shipping and storage. Carrier tape is widely used for presenting devices to pick-and-place machines for automatic placement onto printed circuit boards.

However, traditional carrier tape configurations include a hole at the bottom of each pocket. While these holes offer some advantages, they can be the source of foreign materials (unwanted matter) that can lower yield rates and becomes more problematic as die sizes shrink further.

### BRIEF DESCRIPTION OF THE .DRAWINGS

FIG. 1 is a block diagram depicting a carrier tape, in accordance with some example embodiments.

FIG. 2A is a diagram depicting a pocket in a carrier ape that includes a hole, in accordance with some example embodiments.

FIG. 2B is a diagram depicting a pocket in a carrier tape that does not include a hole, in accordance with some example embodiments.

FIG. 2C is a diagram depicting a pocket in a carrier tape that does not include a hole, in accordance with some example embodiments.

FIG. 3 is a diagram depicting a pocket in a carrier tape that does not include a hole, in accordance with some example embodiments.

FIG. 4 is a diagram depicting a pocket in a carrier tape that does not include a hole having a die being lowered into it, in accordance with some example embodiments.

FIG. 5 shows a flow diagram of a method of creating a side vent designed carrier tape without a center hole to reduce the presence of foreign materials and reduce out of pocket errors, in accordance with some example embodiments.

FIG. 6 a system for producing an electronic package or device according to one example embodiment.

### DESCRIPTION OF EMBODIMENTS

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

Once integrated circuit dies are produced, they need to be able to integrate into microelectronic devices to be useful. In some example embodiments, the dies are attached to printed circuit boards (PCBs) as part of this integration. To bring the dies from the location where they were produced to a pick and place machine (or equivalent), a carrier tape is used. The carrier tape includes a series of pockets that are sized to fit the dies and bring them to the pick and place machine.

Currently, carrier tape usually includes a hole in each pocket that is intended to allow the die to easily settle into the pocket. However, these holes are a source of foreign materials. In the past, the foreign materials that were introduced via the hole were too small to affect dies that were made of larger components.

Efforts to reduce the presence of foreign materials by removing the hole have proven difficult. Without the hole, the air that is displaced when the die settles into the pocket has nowhere to go and often results in the die not sitting flat in the pocket. However, if the pocket is enlarged, the die is no longer held reliable in a given position. Rotation or deployment of the die outside of a predetermined area renders the die difficult to manipulate correctly. Thus a better solution is needed.

In some example embodiments, a pocket can be created that includes a depression with four corners of the tape material outlining the basic height and width of a die. The four corners are placed such that the die will sit in the area defined by the four corners without displacement or rotation.

Each edge (between two corners) also includes a side vent. A side vent is an additional depression section of the pocket that is positioned along each edge such that the four corners of the pocket still define the area into which the die can settle or rest, but allows displaced air to escape. In this way, the die sits flat in the pocket and the air is able to escape through the side vents. This allows the advantages of the hole based pockets without the drawback of introducing additional foreign material.

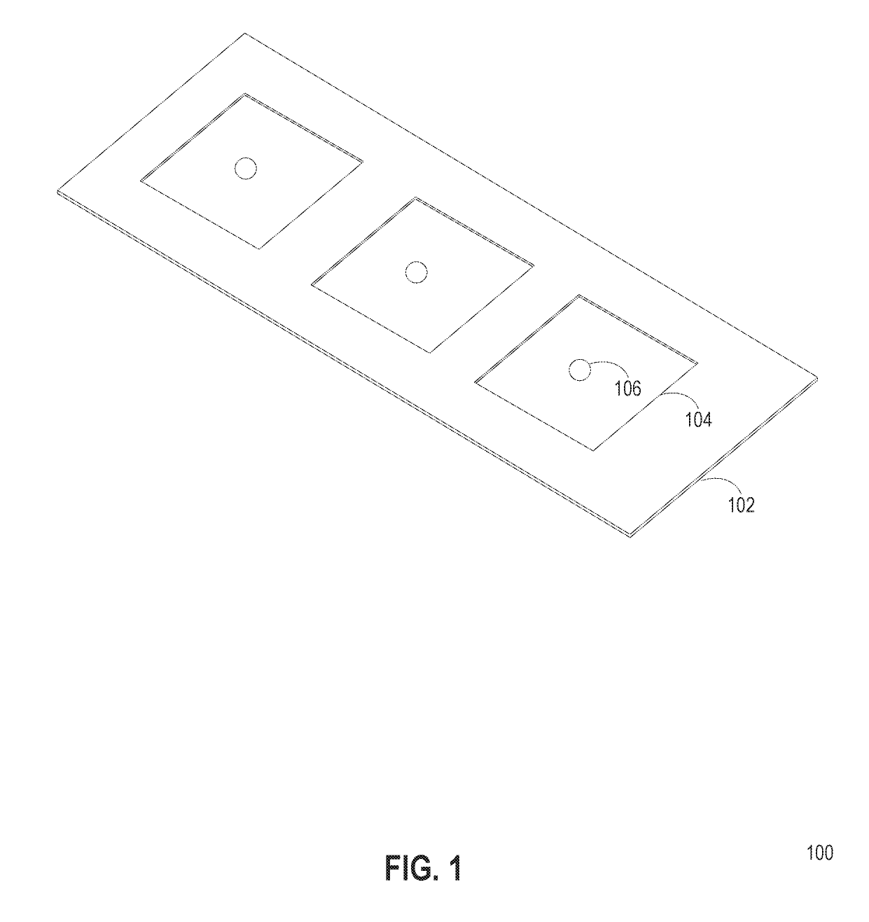

FIG. 1 is a diagram depicting a carrier tape 102 in accordance with some example embodiments. In some example embodiments, the carrier tape is constructed using an appropriate polymer. In some example embodiments, the carrier tape is constructed using an embossed polystyrene plastic or an embossed polycarbonate plastic. In some example embodiments, the carrier tape includes a plurality of pockets 104.

Each pocket is a depression in the carrier tape designed to accommodate a single die. Each die is made of silicon and includes an integrated circuit. In some example embodiments, the carrier tape 102 allows a dies to be moved and stored. In some example embodiments, the dies are carried to a pick and place machine for attachment to a printed circuit board or otherwise used in a component.

In some example embodiments, each pocket 104 includes a hole 106. This hole 106 is situated to allow air to escape downward as it is displaced by a settling die. However, the holes result in the introduction of foreign materials to the pocket.

In some example embodiments, the foreign materials are small pieces of the carrier tape 402 (e.g., stringers) that are very small. In some example embodiments, the stringers vary in size from a few microns to hundreds of microns. These foreign materials prove very difficult to effectively filter out, and can result in yield loss in dies.

In some example embodiments, the foreign materials can short out the electrical connections on the die by connected two components inadvertently. As such, carrier tape with holes in them are becoming increasingly difficult to use effectively to transport dies.

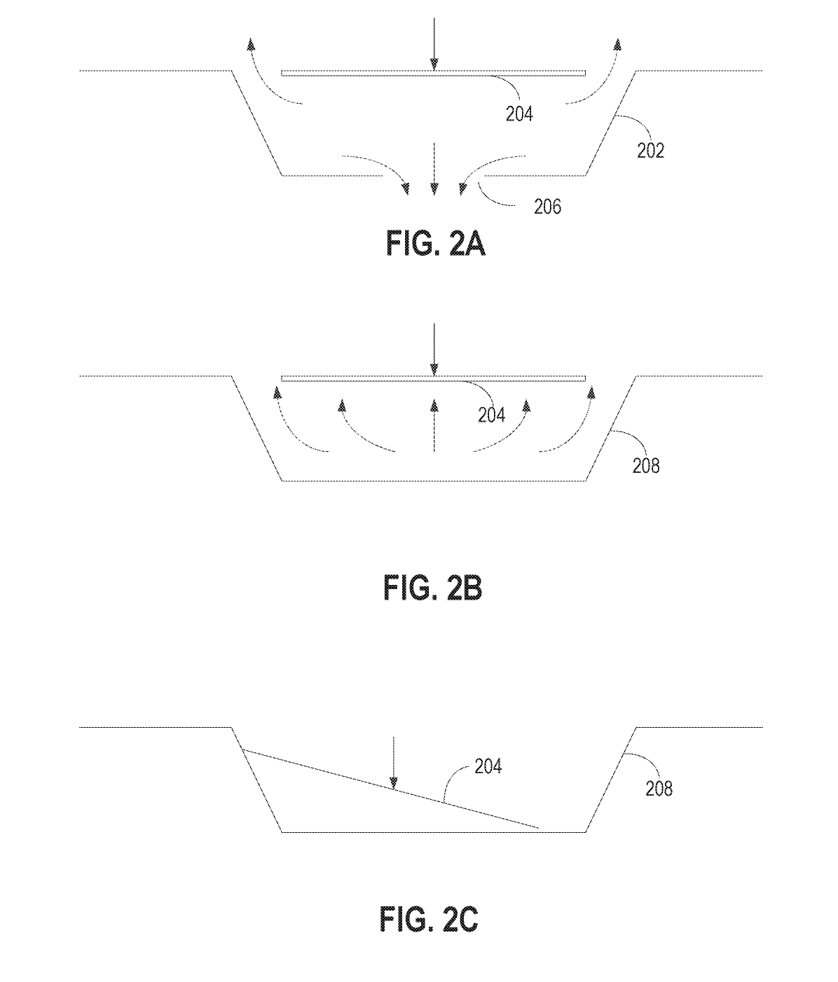

FIG. 2A is a diagram depicting a pocket 202 in a carrier tape (e.g., carrier tape 102 in FIG. 1) that includes a hole 206, in accordance with some example embodiments. In some example embodiments, the diagram illustrates how air moves in the pocket as a die 204 is lowered into it.

As can be seen in the figure, a pocket 202 with a hole 206 allows air from the pocket to escape in two general ways. First air being displaced by the die 204 can move around the sides of the die and go upward. At the same time, displaced air can move down through the hole 206, allowing the die 204 to settle into the pocket 206. Thus, having a whole allows the die to settle evenly, but introduces too many foreign materials. In some example embodiments, a pocket without a hole can be used to eliminate the excess foreign materials.

FIG. 2B is a diagram depicting a pocket 208 in a carrier tape (e.g., carrier tape 102 in FIG. 1) that does not include a hole 206. In some example embodiments, the diagram illustrates how air moves in the pocket as a die 204 is lowered into it.

In accordance with some example embodiments, a pocket 208 without any hole only has one route for displaced air to escape. Thus, as the die 204 is lowered into the pocket 208, air can only escape upward, out of the top of the pocket. As a result, the die 204 is more likely to have trouble settling properly in the pocket.

FIG. 2C is a diagram depicting a pocket 208 in a carrier tape carrier tape 102 in FIG. 1) that does not include a hole 206. In this example, the die has been unable to settle properly because upward moving displaced air prevented the die 204 from settling properly into the pocket.

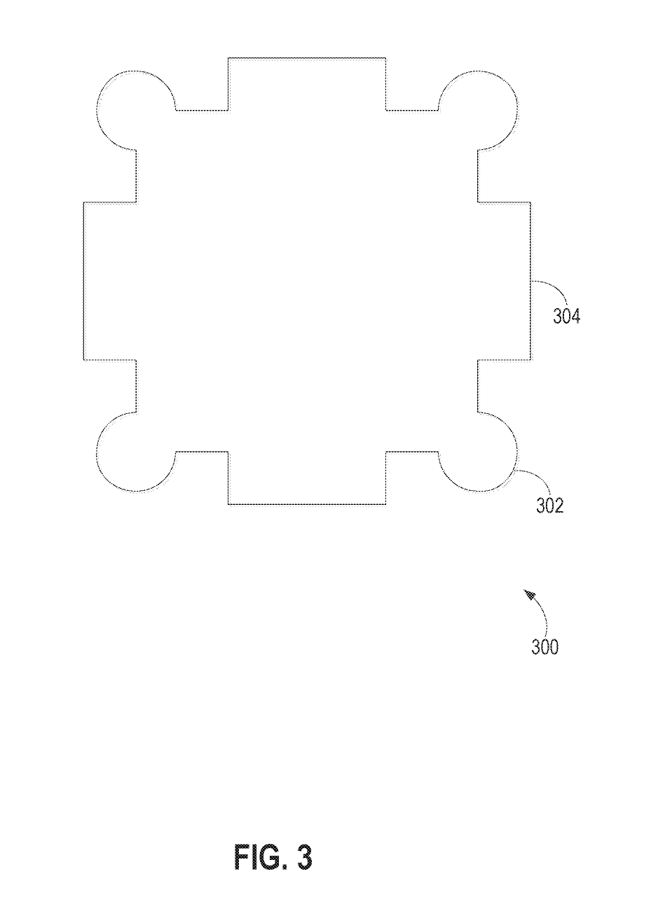

FIG. 3 is a diagram depicting a pocket 300 in a carrier tape (e.g., carrier tape 102 in FIG. 1) that does not include a hole, in accordance with some example embodiments. In some example embodiments, the diagram illustrates how a pocket can be designed to allow proper settling without a hole.

In some example embodiments, the pocket 300 is a depression in a carrier tape that has four corners 302. Each corner is arranged to form a rectangle shape or a square shape. In this way, the corners define an area into which a die can settle.

Between each corner is an edge that defines a side of the rectangle or square. In some example embodiments, along each edge an additional edge pocket is formed. In some example embodiments, the edge pocket is rectangular and extends from the main pocket into the side edges. In other example embodiments, the additional edge pocket is rounded or any other shape, as needed.

In some example embodiments, each corner is rounded to allow the die to easily settle into the square shape. In some example embodiments, the corners are three-quarter circle shapes.

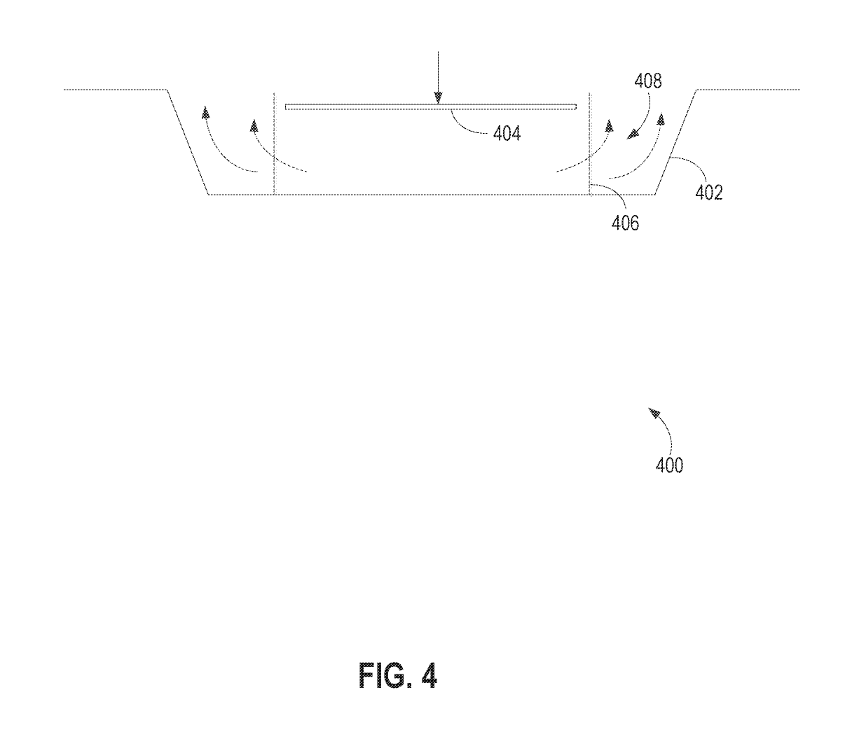

FIG. 4 is a diagram depicting a pocket 400 in a carrier tape that does not include a hole having a die 404 being lowered into it. The pocket 400 also includes walls 406 that define the area into which a die may be lowered.

This pocket is also designed to include additional side pockets 408, which are placed along some or all of the edges and allow air to escape upward around the die 404 without disturbing the die 404 or preventing the die 404 from settling flat in the pocket 400.

Thus, when a die 404 is lowered into the pocket 400, air is displaced. This air can use side pockets 408 to escape from the pocket 400 without disturbing or disrupting the descent of the die 404.

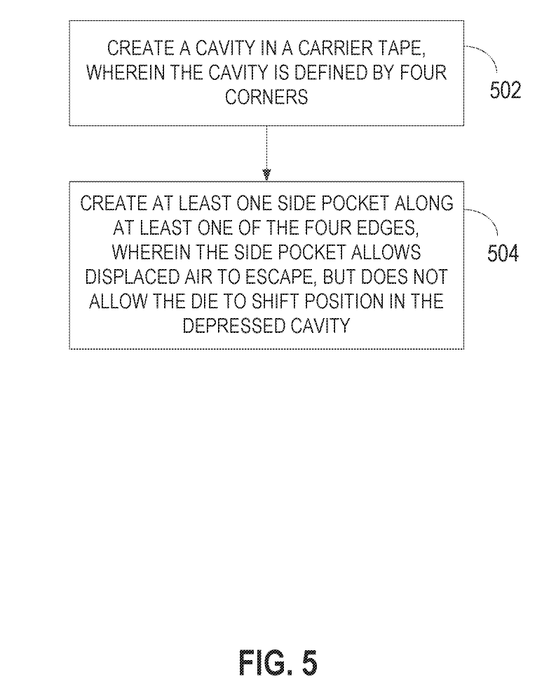

FIG. 5 shows a flow diagram of a method of creating a side vent designed carrier tape without a center hole to reduce the presence of foreign materials and reduce out of pocket errors, in accordance with some example embodiments.

In some example embodiments, a cavity is created (502) in a carrier tape. In some example embodiments, the cavity is a depression in in a carrier tape created by a depressing tool However, no hole is created through the carrier tape. As such, many of the small foreign materials introduced by creating such a hole,

In some example embodiments, the cavity is defined by four corners, the four corners arranged into a shape defining an area designed to hold a silicon die. The carrier tape of claim 1, wherein the four corners are arranged in a rectangular shape. In some example embodiments, the four corners are arrange din a square shape. In some example embodiments, each corner is rounded. In some example embodiments, each corner is shaped as a three-quarters circle.

In some example embodiments, the carrier tape is created from polycarbonate plastic. In some example embodiments, the carrier tape is created from embossed polystyrene plastic.

In some example embodiments, one or more side cavities are created (504) such that they are arranged along one or more edges between two corners; wherein there are no holes through the carrier tape. In some example embodiments, the side cavities or vents are created such that there is one vent along at least one of the four edges. In some example embodiments, the side pocket or vent allows displaced air to escape, but does not allow the die to shift position in the depressed cavity. In some example embodiments, the side the side cavities are rectangular in shape.

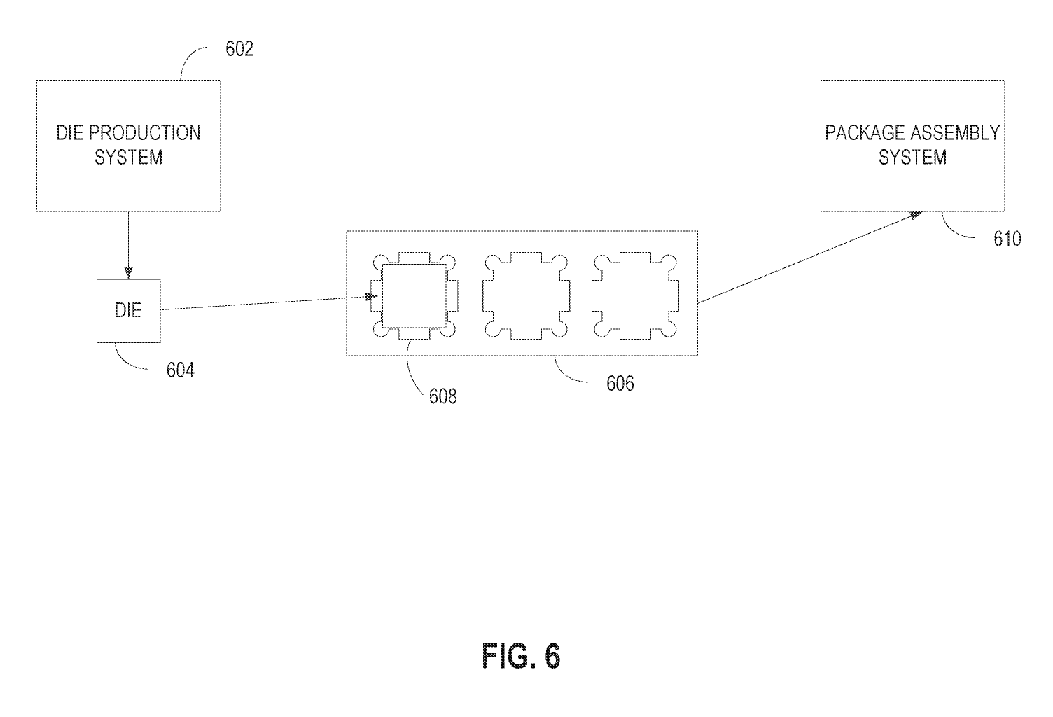

FIG. 6 illustrates a system for producing an electronic package or device 600 as described in the present disclosure. FIG. 6 is included to show an example of a system that uses a carrier tape 606 to move an integrated circuit die from a first location (e.g., a die production system 602) to a second location (e.g., a package assembly system 610).

The die production system 602 can include any of a variety of systems that produce, prepare, modify, or clean integrated circuit dies. Such dies are usually created on a wafer of semiconducting material such as silicon. The die production process may include a series of steps such as cleaning of the wafer material using a solvent such as acetone, photolithography, ion implantation, dry etching, wet etching, electrochemical deposition, chemical-mechanical planarization, physical vapor deposition, thermal treatments, die cutting, and so on.

Once the die production system 602 has produced an integrated circuit die 604, the die 604 can then be deposited in a cavity 608 in the carrier tape 606. In this example embodiment, the carrier tape 606 has a series of cavities 608, each of which for a generally rectangular shape that allows a single die to be deposited. Each cavity has a series of side pockets along their rectangular edges that allow air to escape when the die is settling into the cavity 608. In this way, no hole is necessary in the cavity to vent air and the die 640 is still able to settle flatly in the cavity 608.

The carrier tape 606 enables the die 604 to be moved safely from the first location associated with the die production system 602 to a second location associated with the package assembly system 610. In some example embodiments, the package assembly system 610 removes the die 604 from the cavity 608 of the carrier tape 606 and uses it to assemble an integrated circuit package. In some example embodiments, the die 604 is delivered to a pick and place machine that is part of a package assembly system 610.

In some example embodiments, the first location of the die production system 602 and the second location of the package assembly system are in the same facility such that the carrier tape is moved only within that facility. In other example embodiments, the first location and the second location are located remotely in separate facilities and the carrier ape is used to move the die from one facility to another facility.

### ADDITIONAL NOTES AND EXAMPLES

Example 1 is a carrier tape for storing and transporting dies. The carrier tape comprising: cavity in the carrier tape, wherein the cavity is defined by four corners, the four corners arranged into a shape defining an area designed to hold a silicon die; and one or more side cavities arranged along one or more edges between two corners; wherein there are no holes through the carrier tape for air venting.

In example 2, the subject matter of example 1 wherein the four corners are arranged in a rectangular shape.

in example 3, the subject matter of example 1 wherein the four corners are arranged in a square shape.

In example 4, the subject matter of example 1 wherein each corner is rounded.

In example 5, the subject matter of example 4 wherein each corner is shaped as a three-quarters circle.

In example 6, the subject matter of example 1 wherein the carrier tape is created from a polymer.

In example 7, the subject matter of example 1 wherein the carrier tape is created from polycarbonate plastic.

In example 8, the subject matter of example 1 wherein the carrier tape is created from embossed polystyrene plastic.

In example 9, the subject matter of example 1 wherein the side cavities are rectangular in shape.

Example 10 is a method of constructing a carrier tape for storing and transporting die. The method comprises creating a depressed cavity in the carrier tape without creating a hole through the tape, wherein the cavity is defined by four corners, with four edges between the corners and wherein the cavity is conformed to hold a silicon die; and creating at least one side pocket along at least one of the four edges, wherein the side pocket allows displaced air to escape, but does not allow the die to shift position in the depressed cavity.

In example 11, the subject matter of example 10 wherein the four corners are arranged in a rectangular shape.

In example 12, the subject matter of example 10 wherein the four corners are arranged in a square shape.

In example 13, the subject matter of example 10 wherein each corner is rounded.

In example 14, the subject matter of example 13 wherein each corner is shaped as a three-quarters circle.

In example 15, the subject matter of example 10 wherein the carrier tape is created from a polymer.

In example 16, the subject matter of example 10 wherein the carrier tape is created from polycarbonate plastic.

In example 17, the subject matter of example 10 wherein the carrier tape is created from embossed polystyrene plastic.

In example 18, the subject matter of example 10 wherein the side cavities are rectangular in shape.

Example 19 is a computer-readable storage medium storing instructions that, when executed by the one or more processors of a machine, cause the machine to create a depressed cavity in the carrier tape without creating a hole through the tape, wherein the cavity is defined by four corners, with four edges between the corners and wherein the cavity is conformed to hold a silicon die; and create at least one side pocket along at least one of the four edges, wherein the side pocket allows displaced air to escape, but does not allow the die to shift position in the depressed cavity.

In example 20, the subject matter of example 19 wherein the four corners are arranged in a rectangular shape.

In example 21, the subject matter of example 19 wherein the four corners are arranged in a square shape.

In example 22, the subject matter of example 19 wherein each corner is rounded.

In example the subject matter of example 22 wherein each corner is shaped as a three-quarters circle.

In example 24, the subject matter of example 19 wherein the carrier tape is created from a polymer.

In example 25, the subject matter of example 19 wherein the carrier tape is created from polycarbonate plastic.

In example 26, the subject matter of example 19 wherein the carrier tape is created from embossed polystyrene plastic.

In example 27, the subject matter of example 19 wherein the side cavities are rectangular in shape.

Example 28 is an apparatus comprising means for performing any of the methods of examples 10-18.

Example 29 is an apparatus for constructing a carrier tape for storing and transporting die, the apparatus comprising: means for creating a depressed cavity in the carrier tape without creating a hole through the tape, wherein the cavity is defined by four corners, with four edges between the corners and wherein the cavity is conformed to hold a silicon die; and means for creating at least one side pocket along at least one of the four edges, wherein the side pocket allows displaced air to escape, but does not allow the die to shift position in the depressed cavity.

In example 30, the subject matter of example 29 wherein the four corners are arranged in a rectangular shape,

In example 31, the subject matter of example 29 wherein the four corners are arranged in a square shape.

In example 32, the subject matter of example 29 wherein each corner is rounded.

In example 33, the subject matter of example 32 wherein each corner is shaped as a three-quarters circle.

In example 34, the subject matter of example 29 wherein the carrier tape is created from a polymer.

In example 35, the subject matter of example 29 wherein the carrier tape is created from polycarbonate plastic.

In example 36, the subject matter of example 29 wherein the carrier tape is created from embossed polystyrene plastic.

In example 37, the subject matter of example 29 wherein the side cavities are rectangular in shape.

### Term Usage

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the inventive subject matter has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to any single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

The terminology used in the description of the example embodiments herein is for the purpose of describing particular example embodiments only and is not intended to be limiting. As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context.

1. A carrier tape, the carrier tape comprising:
a cavity in the carrier tape, wherein the cavity is defined by four corners, the four corners arranged into a shape defining an area designed to hold a silicon die; and
one or more side cavities arranged along one or more edges between two corners; wherein there are no holes through the carrier tape for air venting.

2. The carrier tape of claim 1, wherein the four corners are arranged in a rectangular shape.

3. The carrier tape of claim 1, wherein the four corners are arranged in a square shape.

4. The carrier tape of claim 1, wherein each corner is rounded.

5. The carrier tape of claim 4, wherein each corner is shaped as a three-quarters circle.

6. The carrier tape of claim 1, wherein the carrier tape is created from a polymer.

7. The carrier tape of claim 1, wherein the carrier ape is created from polycarbonate plastic.

8. The carrier tape of claim 1, wherein the carrier tape is created from embossed polystyrene plastic.

9. The carrier ape of claim 1, wherein the side cavities are rectangular in shape.

10. A method of constructing a carrier tape for storing and transporting further comprising:
creating a depressed cavity in the carrier tape without creating a hole through the tape, wherein the cavity is defined by four corners, with four edges between the corners and wherein the cavity is conformed to hold a silicon die; and
creating at least one side pocket along at least one of the four edges, wherein the side pocket allows displaced air to escape, but does not allow the die to shift position in the depressed cavity.

11. The method of claim 10, wherein the four corners are arranged in a rectangular shape.

12. The method of claim 10, wherein the four corners are arranged in a square shape.

13. The method of claim 10, wherein each corner is rounded.

14. The method of claim 13, wherein each corner is shaped as a three-quarters circle.

15. The method of claim 10, wherein the carrier tape is created from polycarbonate plastic.

16. The method of claim 10, wherein the carrier tape is created from embossed polystyrene plastic.

17. A method of manufacturing a semiconductor device, the method comprising:
creating an integrated circuit die;
depositing the integrated circuit die in a cavity in a carrier tape; wherein the cavity is defined by four corner and includes at least one side pocket along an edge of the cavity and wherein the carrier tape is continuous within the cavity; and
using the carrier tape to transport the integrated circuit die from a first location to a second location.

18. The method of claim 17, wherein the four corners are arranged in a rectangular shape.

19. The method of claim 17, wherein the four corners are arranged in a square shape.

20. The method of claim 17, wherein each corner is rounded.
